(19) United States
(12) Patent Application Publication
(10) Pub. No.: US 2021/0151496 A1
(43) Pub. Date: May 20, 2021

(54) DISPLAY SUBSTRATE AND MANUFACTURING METHOD THEREOF, AND DISPLAY DEVICE

(71) Applicant: BOE Technology Group Co., Ltd., Beijing (CN)

(72) Inventors: Huijuan WANG, Beijing (CN); Peilin ZHANG, Beijing (CN); Zhenhua LV, Beijing (CN); Yang YOU, Beijing (CN)

(21) Appl. No.: 16/863,091

(22) Filed: Apr. 30, 2020

(30) Foreign Application Priority Data
Nov. 15, 2019 (CN) 201911125161.2

(51) Int. Cl. H01L 27/15; H01L 33/50; H01L 33/00

(52) U.S. Cl. CPC H01L 27/156; H01L 2933/0041; H01L 33/0093; H01L 33/505

(57) ABSTRACT

Provides are a display substrate and a manufacturing method thereof, a display device. The display substrate includes a base substrate; a micro LED backlight array, including a first sub-array of micro LEDs and a second sub-array of micro LEDs; a color conversion layer on the micro LED backlight array, the color conversion layer including: a first color conversion unit array, an orthogonal projection of which on the base substrate overlaps with that of the first sub-array of micro LEDs on the base substrate and does not overlap with that of the second sub-array of micro LEDs on the base substrate; a second color conversion unit array, an orthogonal projection of which on the base substrate overlaps with that of the second sub-array of the micro LEDs on the base substrate and does not overlap with that of the first sub-array of micro LEDs on the base substrate.

### CROSS-REFERENCE TO RELATED APPLICATIONS

The present application claims the priority of the Chinese Patent Application No. 201911125161.2, filed on Nov. 15, 2019, the content of which is incorporated herein by reference in its entirety.

### TECHNICAL FIELD

The present disclosure relates to the field of micro LED display technology, in particular to an LED display substrate and a manufacturing method thereof, and a display device.

### BACKGROUND

A micro LED (micro Light Emitting diode) refers to an LED with a size in the micrometer level. The micro LED can be directly used as a light emitting sub-pixel since the size thereof is already small to a sub-pixel level. The micro LED may be cooperated with a TFT (thin Film transistor) back plate to form a self-luminous active matrix micro LED display device. Compared with Active Matrix Organic Light Emitting Diode (AMOLED) and Liquid Crystal Display (LCD), the micro LED has advantages of no backlight being required, high light source utilization rate, high brightness, extremely high contrast ratio, nanosecond-level response time, long service life and extremely wide operating temperature. The advantages above enable the micro LED to be expected to become a mainstream display technology in the future.

### SUMMARY

In one aspect, a micro LED display substrate is provided, which includes: a base substrate; a micro LED backlight array capable of emitting backlight on the base substrate, the micro LED backlight array including a first sub-array of micro LEDs and a second sub-array of micro LEDs; and a color conversion layer on the micro LED backlight array, the color conversion layer including: a first color conversion unit array including a plurality of first color conversion units, each of the plurality of first color conversion units including a first photoluminescence color conversion material that converts light emitted from the first sub-array of micro LEDs into light of a first color, an orthogonal projection of the first color conversion unit array on the base substrate overlaps with an orthogonal projection of the first sub-array of micro LEDs on the base substrate and does not overlap with an orthogonal projection of the second sub-array of micro LEDs on the base substrate; and a second color conversion unit array including a plurality of second color conversion units, each of the plurality of first color conversion units including a second photoluminescence color conversion material that converts light emitted from the second sub-array of micro LEDs into light of a second color, the light of the second color is different from the light of the first color, and an orthogonal projection of the second color conversion unit array on the base substrate overlaps with the orthogonal projection of the second sub-array of the micro LEDs on the base substrate and does not overlap with the orthogonal projection of the first sub-array of micro LEDs on the base substrate.

In some embodiments, the micro LED backlight array further includes a third sub-array of micro LEDs, and the color conversion layer further includes: a third color conversion unit array including a plurality of third color conversion units, each of the plurality of third color conversion units including a third photoluminescence color conversion material that converts light emitted from the third sub-array of micro-LEDs into light of a third color, the light of the third color is different from the light of the first color and the light of the second color, and an orthogonal projection of the third color conversion unit array on the base substrate overlaps with an orthogonal projection of the third sub-array of micro LEDs on the base substrate and does not overlap with the orthogonal projections of the first sub-array of micro-LEDs and the second sub-array of micro-LEDs on the base substrate.

In some embodiments the first color conversion units in the first color conversion unit array, the second color conversion units in the second color conversion unit array, and the third color conversion units in the third color conversion unit array are arranged in multiple rows and multiple columns, the first color conversion units, the second color conversion units, and the third color conversion units are sequentially arranged along row and column directions, and one first color conversion unit, one second color conversion unit, and one third color conversion unit, which are adjacent in turn, as sub-pixels, constitute one pixel of the display substrate.

In some embodiments the micro LED backlight array emits purple light, the light of the first color is red light, the light of the second color is green light, and the light of the third color is blue light.

In some embodiments, the micro LED backlight array further includes a third sub-array of micro LEDs, and the color conversion layer further includes: a transparent unit array including a plurality of transparent units, each of the plurality of transparent units transmitting light emitted from the third sub-array of micro LEDs of the micro LED backlight array, an orthographic projection of the transparent unit array on the base substrate overlaps with an orthographic projection of the third sub-array of micro LEDs on the base substrate and does not overlaps with the orthographic projections of the first sub-array of micro LEDs and the second sub-array of micro LEDs on the base substrate.

In some embodiments, the first color conversion units in the first color conversion unit array, the second color conversion units in the second color conversion unit array, and the transparent units in the transparent unit array are arranged in multiple rows and multiple columns, the first color conversion units, the second color conversion units, and the transparent units are sequentially arranged along row and column directions, and one first color conversion unit, one second color conversion unit, and one transparent unit, which are adjacent in turn, as sub-pixels, constitute one pixel of the display substrate.

In some embodiments, the micro LED backlight array emits blue light, the light of the first color is red light, and the light of the second color is green light.

In some embodiments, the micro LED backlight may is an actively driven micro LED backlight array.

In one aspect, a display device including the display substrate above and a driving circuit for driving the micro LED backlight array of the display substrate is provided.

In one aspect, a manufacturing method of a display substrate is provided, the manufacturing method including: providing a base substrate; providing a micro LED backlight array on the base substrate, the micro LED backlight array includes a first sub-array of micro LEDs and a second sub-array of micro LEDs; and forming a color conversion layer on the micro LED backlight array, the color conversion layer includes: a first color conversion unit array including a plurality of first color conversion units, each of the plurality of first color conversion units including a first photoluminescence color conversion material that converts light emitted from the first sub-array of micro LEDs into light of a first color, an orthogonal projection of the first color conversion unit array on the base substrate overlaps with an orthogonal projection of the first sub-array of micro LEDs on the base substrate and does not overlap with an orthogonal projection of the second sub-array of micro LEDs on the base substrate; and a second color conversion unit array including a plurality of second color conversion units, each of the plurality of first color conversion units including a second photoluminescence color conversion material that converts light emitted from the second sub-array of micro LEDs into light of a second color, the light of the second color is different from the light of the first color, and an orthogonal projection of the second color conversion unit array on the base substrate overlaps with the orthogonal projection of the second sub-array of micro LEDs on the base substrate and does not overlap with the orthogonal projection of the first sub-array of micro LEDs on the base substrate.

In some embodiments, the micro LED backlight array further includes a third sub-array of micro LEDs and the color conversion layer further includes: a third color conversion unit array including a plurality of third color conversion units, each of the plurality of third color conversion units including a third color light material that converts light emitted from the third sub-array of micro LEDs into light of a third color, the light of the third color is different from the light of the first color and the light of the second color, an orthogonal projection of the third color conversion unit array on the base substrate overlaps with an orthogonal projection of the third sub-array of micro LEDs on the base substrate and does not overlap with the orthogonal projections of the first sub-array of micro LEDs and the second sub-array of micro LEDs on the base substrate, forming the color conversion layer includes: providing an imprinting master, the imprinting master includes a protrusion array; providing a soluble plate; forming, by adopting a nano-imprinting process, a groove array of multiple rows and multiple columns on the soluble plate by using the protrusion array on the imprinting master, the groove array includes a first sub-array of grooves, a second sub-array of grooves and a third sub-array of grooves, and the first sub-array of grooves, the second sub-array of grooves and the third sub-array of grooves are sequentially arranged along row and column directions of the groove array; filling a first photoluminescence color conversion material into the first sub-array of grooves, filling a second photoluminescence color conversion material into the second sub-array of grooves, and filling a third color light material into the third sub-array of grooves; turning over the soluble plate filled with the first photoluminescence color conversion material, the second photoluminescence color conversion material and the third photoluminescence color conversion material and then placing the soluble plate on the micro-LED backlight array, an orthographic projection of the first sub-array of grooves on the base substrate overlaps with the orthographic projection of the first sub-array of micro LEDs on the base substrate and does not overlap with the orthographic projections of the second sub-array of micro LEDs and an orthographic projection of the third sub-array of micro LEDs on the base substrate; an orthographic projection of the second sub-array of grooves on the base substrate overlaps with an orthographic projection of the second sub-array of micro-LEDs on the base substrate and does not overlap with the orthographic projection of the first sub-array of micro LEDs and the orthographic projection of the third sub-array of micro LEDs on the base substrate; and an orthographic projection of the third sub-array of grooves on the base substrate overlaps with the orthographic projection of the third sub-array of micro LEDs on the base substrate and does not overlap with the orthographic projection of the first sub-array of micro LEDs on the base substrate and the orthographic projection of the second sub-array of micro LEDs on the base substrate; and dissolving the soluble plate, leaving, on the micro LED backlight array, the first photoluminescence color conversion material to form the first color conversion unit array, leaving, on the micro LED backlight array, the second photoluminescence color conversion material to form the second color conversion unit array, and leaving, on the micro LED backlight array, the third color light material to form the third color conversion unit array.

In some embodiments, the soluble plate is a polyvinyl alcohol plate.

In some embodiments, the imprint master is one selected from hard glass, nickel, and PMMA.

In some embodiments, the third color light material includes a third photoluminescence color conversion material or a transparent material, and the third photoluminescence color conversion material converts light emitted from the third sub-array of micro-LEDs into the light of the third color.

In some embodiments, the photoluminescence color conversion material includes a quantum dot material or a fluorescent photoluminescence color conversion material, and the transparent material includes scattering particles.

In some embodiments, the dissolving the soluble plate includes dissolving the soluble plate with an aqueous solvent.

In some embodiments, the providing the micro LED backlight array includes: growing a micro LED array on the single wafer; and transferring the micro LED array from the single wafer to the base substrate to form the micro LED backlight array.

### BRIEF DESCRIPTION OF THE DRAWINGS

FIG. 1 illustrates a cross-sectional view of a display substrate according to an embodiment of the present disclosure;

FIG. 2 illustrates a top view of a display substrate according to an embodiment of the present disclosure;

FIG. 3 illustrates a cross-sectional view of a display substrate according to an embodiment of the present disclosure;

FIG. 4 illustrates a top view of a display substrate according to an embodiment of the present disclosure;

FIG. 5 illustrates a flow chart of a manufacturing method of a display substrate according to an embodiment of the present disclosure;

FIG. 6 illustrates a flow chart of a manufacturing method of a color conversion layer according to an embodiment of the present disclosure;

FIG. 7 illustrates a schematic diagram of an imprinting master according to an embodiment of the present disclosure; and

FIG. 8 illustrates a schematic diagram of steps of a manufacturing method of a display substrate according to an embodiment of the present disclosure.

### DETAILED DESCRIPTION

In the related art, micro LEDs of red, green and blue (RGB) need to be respectively grown on different wafer substrates (including sapphire, GaAs, monocrystalline silicon, SiC, etc.) during a manufacturing progress, and need to be manufactured separately. Among them, the micro LEDs of blue and green are relatively mature in development and have good electroluminescence performance, but the micro LED of red is relatively immature in development and has poor electroluminescence performance. When a display device is being prepared, the micro LEDs need to be transferred to the TFT back plate from a wafer substrate to realize active matrix driving. Therefore, the micro LEDs of above three colors need to be transferred separately, thereby resulting in a complex transfer process, low yield, high cost, and low speed. In addition, a wavelength fluctuation among the grown LED chips is typically greater than 5 nm on a same wafer substrate (e.g., 4″ sapphire substrate). When these LED chips are directly used as light-emitting pixels without sorting, chromaticity difference can be felt by human eyes. However, for high resolution applications (such as a phone with FHD (Full High Definition)), the micro LED chip has a size less than 50 μm, and the existing sorting solution by means of probe test for the LED chips is no longer applicable. Therefore, there is no fast, accurate detection and sorting solution for the micro LEDs.

In view of the above problems, a micro LED having a layered structure composed of a blue LED, a color conversion material for white light, and a color filter has been proposed. Specifically, micro LEDs of blue or green are arranged as a light source on a TFT backplate, and a color conversion layer conversing blue or green light into white light is arranged above the micro LEDs of blue or green. Thereby a blue or green light lattice is converted into a white light lattice. Then an RGB color filter layer is arranged above the color conversion layer, so that color display is realized. However, thus structure uses the color filter layer to filter the white light, so that a large amount of light energy and the light emitting performance are lost while the process is simplified.

Accordingly, the present disclosure provides a display substrate that can overcome the transfer and sorting problems of micro LEDs of various colors, avoid the use of the color filters, and avoid the light energy loss of the above-described solution using the color filters by directly introducing color conversion materials facing to sub-pixels.

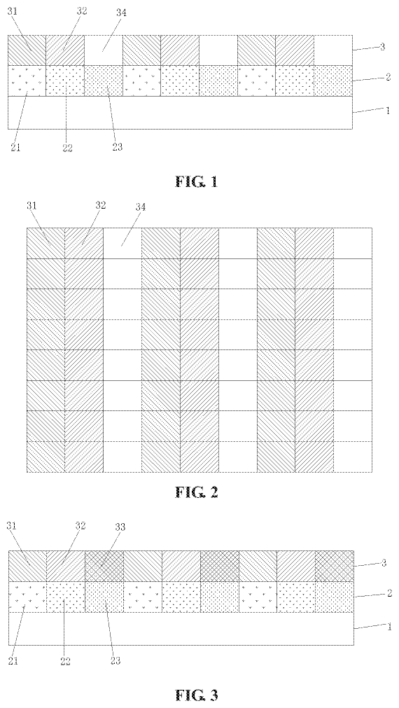

As shown in FIGS. 1 and 2, the display substrate includes: a base substrate 1; a micro LED backlight array 2 capable of emitting backlight on the base substrate. The micro LED backlight array 2 includes a first sub-array of micro LEDs and a second sub-array of micro LEDs; and a color conversion layer 3 above the micro LED backlight array 2. The first sub-array of micro LEDs includes first LEDs 21, and the second sub-array of micro LEDs includes second LEDs 22.

As shown in FIGS. 1 and 2, the color conversion layer 3 includes a first color conversion unit array and a second color conversion unit array. The first color conversion unit array includes a plurality of first color conversion units 31, and each of the first color conversion units 31 includes a first photoluminescence color conversion material that converts light emitted from a corresponding micro LED of the first sub-array of micro LEDs into first color light. An orthographic projection of the first color conversion unit array on the base substrate 1 overlaps with an orthographic projection of the first sub-array of micro LEDs on the base substrate 1 and does not overlap with an orthographic projection of the second sub-array of micro LEDs on the base substrate 1. The second color conversion unit array includes a plurality of second color conversion units 32, and each of the second color conversion units 32 includes a second photoluminescence color conversion material that converts light emitted from a corresponding micro LED of the second sub-array of micro LEDs into second color light. The second color light is different from the first color light. An orthographic projection of the second color conversion unit array on the base substrate 1 overlaps with the orthographic projection of the second sub-array of micro LEDs on the base substrate 1, and does not overlap with the orthographic projection of the first sub-array of micro LEDs and the orthographic projection of the first color conversion unit array on the base substrate 1.

In the display substrate in the present disclosure, the color conversion unit containing the photoluminescence color conversion material is independently arranged for each micro LED, so that no color filter is required for filtering light, and light energy loss is reduced.

The display substrate of the present disclosure uses a micro LED array as a backlight source. The micro LED backlight array 2 is arranged on the base substrate 1. The base substrate 1 may be, for example, an array substrate, so that it can be combined with the micro LED backlight array 2 to form an active matrix LED. Each micro LED in the micro LED backlight array may emit light individually. Each micro LED of the micro LED backlight array may correspond to a sub-pixel of the display substrate. In the micro LED backlight array 2, all micro LEDs emit backlight with a same color.

The micro LED backlight array 2 includes a first sub-array of micro LEDs and a second sub-array of micro LEDs. In general, the first sub-array of micro-LEDs may correspond to sub-pixels of first color, and the second sub-array of micro-LEDs may correspond to sub-pixels of second color. In other words, light emitted from each LED of the first sub-array of micro-LEDs will be converted into light of first color, and light emitted from each LED of the second sub-array of micro-LEDs will be converted into light of second color. One LED of the first sub-array of micro-LEDs and one LED of the second sub-array of micro-LEDs, which are adjacent to each other, may constitute two sub-pixels in one pixel. Thus, in general, positions of the first sub-array of micro-LEDs and the second sub-array of micro-LEDs correspond to positions of sub-pixels of two colors.

As described below, there may also be a third sub-array of micro-LEDs including third LEDs 23 corresponding to sub-pixels of a third color. Depending on a specific arrangement of the sub-pixels, one skilled in the art can arrange the sub-arrays of micro LEDs accordingly to form a backlight array.

A color conversion layer is arranged on a light-exiting side of the micro LEDs. The color conversion layer includes a first color conversion unit array including a plurality of first color conversion units 31. Each of the first color conversion units 31 includes a first photoluminescence color conversion material that converts light emitted from the first sub-array of the micro LEDs into light of the first color, and an orthogonal projection of the first color conversion unit array on the base substrate 1 overlaps with an orthogonal projection of the first sub-may of the micro LEDs on the base substrate 1 and does not overlap with an orthogonal projection of the second sub-array of the micro LEDs on the base substrate 1. The color conversion layer further includes a second color conversion unit array including a plurality of second color conversion units 32. Each of the second color conversion unit includes a second photoluminescence color conversion material that converts light emitted from the second sub-array of the micro LEDs into light of the second color. The light of the second color is different from the light of the first color, and an orthogonal projection of the second color conversion unit array on the base substrate 1 overlaps with the orthogonal projection of the second sub-array of the micro LEDs on the base substrate 1, and does not overlap with the orthogonal projection of the first sub-array of the micro LEDs and the orthogonal projection of the first color conversion unit array on the base substrate 1.

In the present disclosure, the overlapping may be at least partially overlapping or a completely overlapping. In this way, the backlight emitted from the light-exiting side of the first sub-array of micro LEDs is at least partially irradiated to the first color conversion units 31, and the first photoluminescence color conversion material therein is caused to convert the received light into the light of the first color. Orthographic projections of the first color conversion units 31 on the base substrate may completely cover the orthographic projection of the first sub-array of micro LEDs on the base substrate, so that all the backlight emitted from the first sub-array of micro LEDs may be utilized. The orthographic projection of the first color conversion unit array on the base substrate 1 and the orthographic projection of the second sub-array of the micro-LEDs on the base substrate 1 do not overlap with each other, so that the first photoluminescence color conversion material cannot convert the light from the second sub-array of the micro-LEDs. The orthographic projections of the second color conversion units 32 on the base substrate may completely cover the orthographic projection of the second sub-array of micro LEDs on the base substrate, so that all the backlight emitted from the second sub-array of micro LEDs may be utilized. The orthographic projection of the second color conversion unit array on the base substrate 1 and the orthographic projection of the first sub-array of the micro-LEDs on the base substrate 1 do not overlap with each other, so that the second photoluminescence color conversion material cannot convert the light from the first sub-array of the micro-LEDs. In addition, the orthographic projections of the first color conversion units 31 on the base substrate and the orthographic projections of the second color conversion unit 32 on the base substrate do not overlap with each other, and thus do not interfere with each other.

The photoluminescence color conversion material in the present disclosure may be any material that can directly convert the backlight into light of other colors through photoluminescence, such as a quantum dot material, a fluorescent photoluminescence color conversion material, and the like.

Therefore, a display substrate capable of performing multicolor display can be formed without using color filters.

As described above, the sub-pixels of the first color and sub-pixels of the second color are formed. A conventional display substrate has sub-pixels of three colors. In the present disclosure, a sub-pixel of a third color may be formed by either a photoluminescence color conversion material or directly by a backlight. In the present disclosure, the terms of first, second, and third are only for the purpose of distinction.

In particular, the micro LED backlight array 2 further includes a third sub-array of micro LEDs, and the color conversion layer further includes a third color conversion unit array including a plurality of third color conversion units 33. Each of the third color conversion units 33 includes a third photoluminescence color conversion material that converts light emitted from the third sub-array of micro LEDs into light of the third color. The light of the third color is different from the light of the first color and the light of the second color. An orthogonal projection of the third color conversion unit array on the base substrate 1 overlaps with an orthogonal projection of the third sub-array of micro LEDs on the base substrate 1, and does not overlap with orthogonal projections of the first sub-array of micro LEDs, the second sub-array of micro LEDs, the first color conversion unit array, and the second color conversion unit array on the base substrate 1.

Corresponding to the sub-pixels which are usually arranged in an array on the display substrate, the first color conversion units in the first color conversion unit array, the second color conversion units in the second color conversion unit array and the third color conversion units in the third color conversion unit array are arranged in multiple rows and multiple columns. The first color conversion unit 31, the second color conversion unit 32, and the third color conversion unit 33 are sequentially arranged in row and column directions. One of the first color conversion units, one of the second color conversion units, and one of the third color conversion units, which are adjacent in turn, as sub-pixels, constitute one pixel of the display substrate, as shown in FIG. 2.

In above case, color of the backlight is not used as one of colors of the sub-pixels. At this time, a purple micro LED having a shorter emission wavelength may be selected as the backlight source, and the first, second, and third photoluminescence color conversion materials convert purple light into red, green, and blue light, respectively.

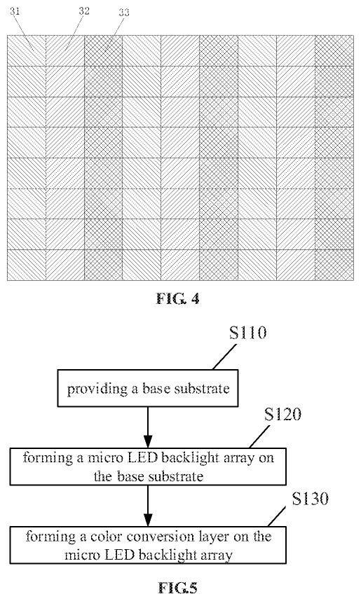

Alternatively, as shown in FIGS. 3 and 4, the color conversion layer may farther include a transparent unit array including a plurality of transparent units 34. The transparent units are transparent to the backlight. An orthogonal projection of the transparent unit array on the base substrate 1 overlaps with the orthogonal projection of the third sub-array of micro LEDs on the base substrate 1, and does not overlap with the orthogonal projections of the first sub-array of micro LEDs, the second sub-array of micro LEDs, the first color conversion unit array, and the second color conversion unit array on the base substrate 1.

Corresponding to the sub-pixels which are usually arranged in an array on the display substrate, the first color conversion units 31 in the first color conversion unit array, the second color conversion units 32 in the second color conversion unit array, and the transparent units 34 in the transparent unit array are arranged in multiple rows and multiple columns. The first color conversion unit, the second color conversion unit, and the transparent unit are sequentially arranged in row and column directions, and one of the first color conversion units, one of the second color conversion units, and one of the transparent units, which are adjacent in turn, as sub-pixels, constitute one pixel of the display substrate.

In this case, the color of the backlight is directly used as one of the colors of the sub-pixel, and the transparent unit array is used only to fill a space in the color conversion layer. At this time, the backlight may be blue, and the first and second photoluminescence color conversion materials convert the blue light into red and green light, respectively. The transparent units may be simply formed of a transparent material.

In order that each micro LED in the micro LED backlight array 2 can emit light individually, active matrix driving may be employed, i.e., the micro LED backlight array is an active matrix micro LED array. At this time, the base substrate 1 may be a TFT array substrate, and is combined with the micro LED backlight array 2 to form the active matrix micro LED array.

As described above, each pixel of the display substrate may include micro LEDs belonging to the first sub-array of micro LEDs, micro LEDs belonging to the second sub-array of micro LEDs, and micro LEDs belonging to the third sub-array of micro LEDs, so that the sub-pixels of each pixel may emit light of the first color, the second color, and the third color. That is, the micro LEDs belonging to the first sub-array of micro LEDs, the micro LEDs belonging to the second sub-array of micro LEDs and the micro LEDs belonging to the third sub-array of micro LEDs are used as the sub-pixels of the first color, the sub-pixels of the second color and the sub-pixels of the third color, respectively. In some implementations, each pixel includes three micro LEDs respectively from the first, second and third sub-arrays of micro LEDs. In this way, each micro LED is used to form one sub-pixel, which is easy to control and high resolution can be achieved. In a case of a four color (e.g. RGBW) display, a fourth sub-array of micro-LEDs may be further included. Required units of the color conversion layer can be set for each micro LED.

In the micro LED display substrate in the present disclosure, only blue or purple micro LEDs, which are developed and mature in the art, are used, so that a full-color display can be accomplished without requiring to manufacture the red and green micro LEDs, moreover, it is not required to transfer the micro LEDs of different colors formed on different base substrates, so that the transfer process can be simplified, the yield can be improved, and the cost can be reduced. In addition, the photoluminescence conversion material is characterized in that the photoluminescence conversion material can absorb exciting light in a certain fluctuation range and emit light with good monochromaticity after converting the absorbed exciting light. Therefore, even if the light emitted from the micro LED fluctuates, wavelength detection and sorting are not needed, and thus the process is further simplified, and the cost is further reduced. Taking the quantum dot materials as an example, a corresponding optimal excitation wavelength can be modulated to be in a range from 445 to 455 nm, so that the fluctuation tolerance of plus or minus 5 nm can be provided for a blue micro LED with a wavelength of 450 nm, for example. This further reduces and simplifies the process, reduces costs, and saves production time for a single product.

FIG. 1 only illustrates an embodiment of the display substrate of the present disclosure. The display substrate includes a micro LED backlight array 2 with a single color, which forms an active matrix micro LED backlight array on, for example, a TFT base substrate 1. The display substrate further includes a color conversion layer 3 including a first color conversion unit array, each first color conversion unit of the first color conversion unit array being indicated as 31, and a second color conversion unit array, each second color conversion unit of the second color conversion unit array being indicated as 32. The light emitted from the micro LEDs (which belong to the first sub-array) whose orthographic projections on the base substrate 1 overlap with orthographic projections of the first color conversion units 31 on the base substrate 1 may be converted into the light of the first color by the first color conversion units 31, and the light emitted from the micro-LEDs (which belong to the second sub-array) whose orthographic projections on the base substrate 1 overlap with orthographic projections of the second color conversion units 32 may be converted into the light of the second color by the second color conversion units 32. Therefore, a color display based on the micro LED array with a single color can be realized without the color filter structure.

As described above, when the color of the micro LED backlight is one of the basic colors of color display, for example, blue, the third color conversion unit array including the third color conversion units 33 may be a transparent unit array, so that light emitted from the micro LEDs (which belong to the third sub-array of micro LEDs) whose orthographic projections on the base substrate 1 overlap with those of the third color conversion units 33 is directly emitted out by the third color conversion units 33. When the color of the micro LED backlight is not one of the basic colors of the color display, such as purple, the third color conversion units 33 may convert the light emitted from the micro LEDs (which belong to the third sub-array of micro LEDs) whose orthographic projections on the base substrate 1 overlap with those of the third color conversion units 33 into the color of the color display, such as blue.

FIG. 1 is merely a schematic illustration of a display substrate in the present disclosure. It will be appreciated that the scheme of the present disclosure may also be used for display of four primary colors, such as RGBW display. Also, sizes of various sub-pixels may be different.

The present disclosure also provides a display device having the above-described display substrate and a driving circuit for driving the display substrate.

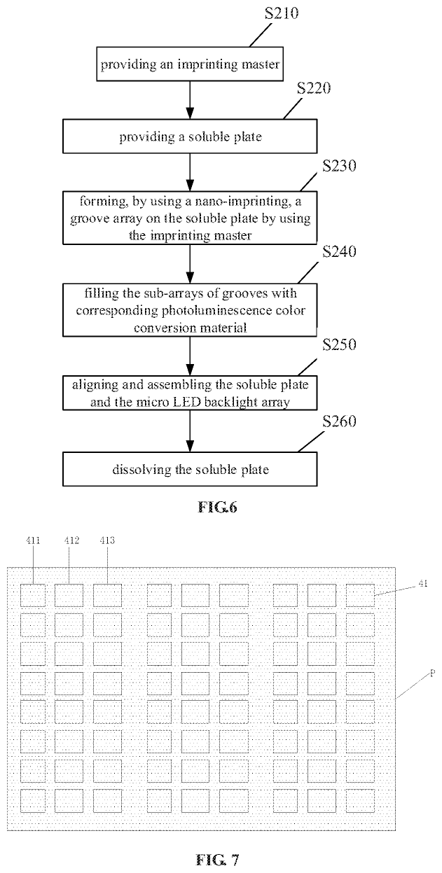

The present disclosure also provides a manufacturing method of a display substrate, as shown in FIG. 5, the manufacturing method includes the following steps S110 to S130. At step S110, a base substrate is provided. At step S120, an micro LED backlight array is formed on the base. At step S130, a color conversion layer is formed on the LED backlight array.

At step S120, a micro LED backlight array capable of emitting backlight is provided on the base. The micro LED backlight array includes a first sub-array of micro-LEDs and a second sub-array of micro LEDs. At step S130, the color conversion layer is provided on the micro LED backlight array. The color conversion layer includes a first color conversion unit array and a second color conversion unit array. The first color conversion unit array includes a plurality of first color conversion units. Each of the first color conversion units includes a first photoluminescence color conversion material that converts light emitted from the first sub-array of micro-LEDs into light of a first color, and an orthogonal projection of the first color conversion unit array on the base substrate overlaps with an orthogonal projection of the first sub-array of the micro LEDs on the base substrate and does not overlap with an orthogonal projection of the second sub-array of the micro LEDs on the base. The second color conversion unit array includes a plurality of second color conversion units. Each of the second color conversion units includes a second photoluminescence color conversion material that converts light emitted from the second sub-array of micro LEDs into light of a second color. The light of the second color is different from the light of the first color. An orthogonal projection of the second color conversion unit array on the base substrate overlaps with an orthogonal projection of the second sub-array of micro LEDs on the base, and does not overlap with the orthogonal projections of the first sub-array of micro LEDs and the first color conversion unit array on the base.

In some implementations, at step S120, the provided micro LED backlight array may further include a third sub-array of micro LEDs. Providing the color conversion layer further includes providing a third color conversion unit array that includes a plurality of third color conversion units. Each of the third color conversion units includes a third color light material that converts light emitted from a third sub-array of micro LEDs into light of a third color. The light of the third color is different from the light of the first color and the light of the second color. An orthogonal projection of the third color conversion unit array on the base substrate overlaps with an orthogonal projection of the third sub-array of micro LEDs on the base substrate and does not overlap with the orthogonal projections of the first sub-array and the second sub-array of micro LEDs on the base. The third color light material includes a third photoluminescence color conversion material or a transparent material. The third photoluminescence color conversion material emits the light of the third color under illumination by light emitted from the third sub-array of micro LEDs, and the transparent material is capable of transmitting light emitted from the third sub-array of the micro LEDs. The transparent material includes scattering particles.

Through the above method, the display substrate of the present disclosure may be formed.

Neither a full-surface coating process of forming a layer of a single photoluminescence color conversion material, nor a photolithography or an inkjet printing method can be used to form the photoluminescence color conversion material array having the aforementioned sub-pixel level resolution. Therefore, the present disclosure provides a manufacturing method of the display substrate by using a nano-imprinting technology.

In an embodiment, as shown in FIG. 6, forming the color conversion layer includes the following steps.

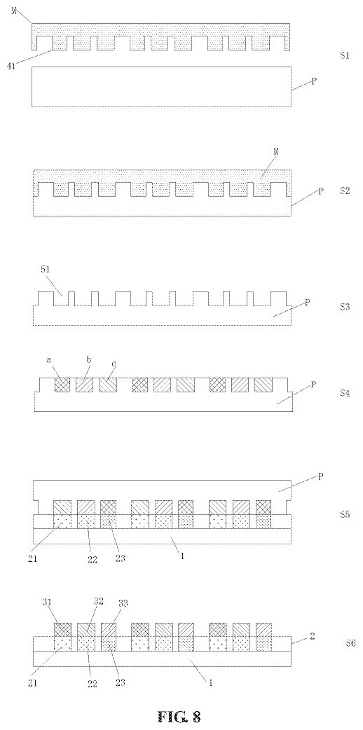

At step S210, providing an imprinting master. The imprinting master includes a protrusion array. As shown in FIG. 7, the imprinting master M includes a protrusion array 41.

At step S220, providing a soluble plate, such as a polyvinyl alcohol plate.

At step S230, forming, by using nano-imprinting, a groove array with multiple rows and columns on the soluble plate P by using the protrusion array 41 on the imprinting master, so that the groove array includes a first sub-array of grooves 411, a second sub-array of grooves 412, and a third sub-array of grooves 413. One groove in the first sub-array of grooves, one groove in the second sub-array of grooves, and one groove in the third sub-array of grooves are arranged sequentially. The interval between adjacent grooves 51 in the groove array is equal to a pixel pitch.

At step S240, filling a first photoluminescence color conversion material into the first sub-array of grooves, filling a second photoluminescence color conversion material into the second sub-array of grooves, and filling a third color light material into the third sub-array of grooves.

At step S250, turning the soluble plate filled with the first and second photoluminescence color conversion materials and the third color light material over and placing it onto the micro-LED backlight array (i.e., aligning and assembling), such that an orthographic projection of the first sub-array of grooves on the base substrate overlaps with the orthographic projection of the first sub-array of micro-LEDs on the base substrate and does not overlap with the orthographic projections of the second sub-array of micro LEDs and the third sub-array of micro LEDs on the base; the orthographic projection of the second sub-array of grooves on the base substrate overlaps with the orthographic projection of the second sub-array of micro LEDs on the base substrate and does not overlap with the orthographic projections of the first and third sub-arrays of micro LEDs on the base; and the orthographic projection of the third sub-array of grooves on the base substrate overlaps with the orthographic projection of the third sub-array of micro LEDs on the base substrate and does not overlap with orthographic projections of the first sub-array of micro LEDs and the second sub-array of micro LEDs on the base.

At step S260, dissolving the soluble plate, so that, on the micro LED backlight array, leaving the first photoluminescence color conversion material to form the first color conversion unit array, leaving the second photoluminescence color conversion material to form the second color conversion unit array, and leaving the third color light material to form the third color conversion unit array.

This embodiment uses the soluble plate on which the grooves are imprinted. A size of the imprinted groove may be of a nano-scale, so that this process may also be referred to as nano-imprinting. Specifically, a nano-imprinting master is prepared with male mold corresponding to grooves. Material of the master may be hard glass, metallic nickel, or a soft mold such as PMMA, etc.: position of the male mold for the nano-scale groove may exactly correspond to a position of a single sub-pixel, so that the array of grooves respectively corresponding to single sub-pixels may be imprinted. After imprinted, the grooves of the soluble plate are filled with different photoluminescence color conversion materials, respectively. The filling may be done by coating.

The material of the soluble plate is selected to be receptive to nano-imprinting and to be dissolved. Furthermore, the material of the soluble plate should have a good affinity with the color conversion material. In some implementations, the material of the soluble plate is polyvinyl alcohol which is insoluble in organic solvents such as kerosene, benzene, carbon tetrachloride, ethyl acetate, methanol, ethylene glycol, isopropanol and the like, but is very soluble in water.

FIG. 8 illustrates a schematic flow chart of an embodiment of the present disclosure.

As shown at S1, a master M and a soluble plate P are first prepared. Subsequently, as shown at S2, the soluble plate P is nano-imprinted by using the master M. The master M is removed to obtain the soluble plate P having an array of grooves as shown at S3. As shown at S4, the grooves are filled with different color conversion materials a, b, and c by using, for example, inkjet printing, and the color conversion materials are preliminarily cured by, for example, drying. Subsequently, as shown at S5, the soluble plate P filled with the color conversion materials is attached to the micro LED array 2. formed on the TFT base substrate 1, and the color conversion material array and the micro LED array are aligned with each other. As shown at S6, the soluble plate P is dissolved by using a solvent, the color conversion materials a, b, and c are further cured and firmly bonded to the micro LED array, and the color conversion layer 3 including the different color conversion units 31, 32, and 33 is formed.

Thus, the display substrate of the present disclosure can be manufactured.

The micro LED backlight array 2 is formed on a single base substrate and is entirely transferred onto the TFT base substrate 1. Therefore, micro LEDs of various colors can be prevented from being formed and transferred respectively, and the colors of light of the micro LEDs are prevented from being sorted.

A PMMA master is prepared by adopting a glass-based or Si-based semiconductor photoetching process, a male mold matrix (namely a protrusion array) of 4K*2K is formed on the PMMA master, which has a minimum characteristic dimension of 10 μm corresponding to 840 ppi, and a height of 8 μm.

A polyvinylalcohol soluble plate having a thickness of 100 μm is prepared. Nano-imprinting is carried out on the soluble plate by using the master under a pressure of 50 KPa. A corresponding groove array is formed on the soluble plate by using the male mold, and a depth of the finally formed groove is 8 μm.

Referring to FIG. 2, an inkjet printing method or a coating method is used to fill red and green conversion materials and a transparent material into the groove array of the soluble plate. Specifically, these two color conversion materials and the transparent material are respectively a red quantum dot material, a green quantum dot material and a material containing scattering particles. Subsequently, drying is performed and a preliminary cure is performed.

A blue micro LED array is grown on a single wafer. Subsequently, it is transferred onto the TFT base substrate by a mass transfer process.

The soluble plate is aligned and assembled to the blue micro LED array on the TFT base. Subsequently, the soluble plate is completely dissolved with an aqueous solvent and removed, leaving a color conversion layer composed of color conversion materials and a transparent material.

Finally, the color conversion layer is further cured by a thermal curing method, and the red, green and blue display device is obtained.

Referring to FIG. 2, an inkjet printing method or a coating method is used to fill the red, green and blue photoluminescence color conversion materials, which are quantum dot materials, into the groove array of the soluble plate. Subsequently, drying is performed and a preliminary cure is performed.

A purple micro LED array is grown on a single wafer. Subsequently, it is transferred onto the TFT base substrate by a mass transfer process.

The soluble plate is aligned and assembled to the purple micro LED array on the TFT base. Subsequently, the soluble plate is completely dissolved with a solvent and removed, leaving a color conversion layer composed of color conversion materials.

Finally, the color conversion layer is further cured by a thermal curing method, and the red, green and blue display device is obtained.

With the manufacturing solution of a micro LED display device, transfers of various micro LEDs are avoided, the sorting of the micro LEDs is avoided, and the optical energy loss caused by the use of color filters is also avoided.

The present disclosure has the advantages of simple process, high yield, low cost, and ultrahigh resolution, high color gamut and high brightness in optical effect.

It will be apparent to those skilled in the art that various changes and modifications can be made in the embodiments of the disclosure without departing from the spirit and scope of the disclosure. Thus, it is intended that the present disclosure also encompass such modifications and variations as fall within the scope of the claims and their equivalents.

What is claimed is:

1. A micro LED display substrate, comprising:
a base substrate;
a micro LED backlight array capable of emitting backlight on the base substrate, the micro LED backlight array comprising a first sub-array of micro LEDs and a second sub-array of micro LEDs; and
a color conversion layer on the micro LED backlight array, the color conversion layer comprising:
a first color conversion unit array comprising a plurality of first color conversion units, each of the plurality of first color conversion units comprising a first photoluminescence color conversion material that converts light emitted from the first sub-array of micro LEDs into light of a first color, wherein an orthogonal projection of the first color conversion unit array on the base substrate overlaps with an orthogonal projection of the first sub-array of micro-LEDs on the base substrate and does not overlap with an orthogonal projection of the second sub-array of micro-LEDs on the base substrate; and
a second color conversion unit array comprising a plurality of second color conversion units, each of the plurality of second color conversion units comprising a second photoluminescence color conversion material that converts light emitted from the second sub-array of micro LEDs into light of a second color, wherein the light of the second color is different from the light of the first color, and an orthogonal projection of the second color conversion unit array on the base substrate overlaps with the orthogonal projection of the second sub-array of the micro LEDs on the base substrate and does not overlap with the orthogonal projection of the first sub-array of micro LEDs on the base substrate.

2. The display substrate of claim 1, wherein
the micro LED backlight array further comprises a third sub-array of micro LEDs, and
the color conversion layer further comprises:
a third color conversion unit array comprising a plurality of third color conversion units, each of the plurality of third color conversion units comprising a third photoluminescence color conversion material that converts light emitted from the third sub-array of micro-LEDs into light of a third color, wherein the light of the third color is different from the light of the first color and the light of the second color, and an orthogonal projection of the third color conversion unit array on the base substrate overlaps with an orthogonal projection of the third sub-array of micro-LEDs on the base substrate and does not overlap with the orthogonal projections of the first sub-array of micro-LEDs and the second sub-array of micro-LEDs on the base substrate.

3. The display substrate of claim 2, wherein the first color conversion units in the first color conversion unit array, the second color conversion units in the second color conversion unit array, and the third color conversion units in the third color conversion unit array are arranged in multiple rows and multiple columns,
wherein the first color conversion units, the second color conversion units, and the third color conversion units are sequentially arranged along row and column directions, and one first color conversion unit, one second color conversion unit, and one third color conversion unit, which are adjacent in turn, as sub-pixels, constitute one pixel of the display substrate.

4. The display substrate of claim 3, wherein the micro LED backlight array emits purple light, the light of the first color is red light, the light of the second color is green light, and the light of the third color is blue light.

5. The display substrate of claim I, wherein
the micro LED backlight array further comprises a third sub-array of micro LEDs, and
the color conversion layer further comprises:
a transparent unit array comprising a plurality of transparent units, each of the plurality of transparent units transmitting light emitted from the third sub-array of micro LEDs of the micro LED backlight array, wherein an orthographic projection of the transparent unit array on the base substrate overlaps with an orthographic projection of the third sub-array of micro LEDs on the base substrate and does not overlaps with the orthographic projections of the first sub-array of micro LEDs and the second sub-array of micro LEDs on the base substrate.

6. The display substrate of claim 5, wherein the first color conversion units in the first color conversion unit array, the second color conversion units in the second color conversion unit array, and the transparent units in the transparent unit array are arranged in multiple rows and multiple columns,
wherein the first color conversion units, the second color conversion units, and the transparent units are sequentially arranged in row and column directions, and one first color conversion unit, one second color conversion unit, and one transparent unit, which are adjacent in turn, as sub-pixels, constitute one pixel of the display substrate.

7. The display substrate of claim 6, wherein the micro LED backlight array emits blue light, the light of the first color is red light, and the light of the second color is green light.

8. The display substrate of claim 1, wherein the micro LED backlight array is an actively driven micro LED backlight array.

9. A display device, comprising the display substrate of claim 1 and a driving circuit for driving the micro LED backlight array of the display substrate.

10. A manufacturing method of a display substrate, the manufacturing method comprising:
providing a base substrate;
providing a micro LED backlight array on the base substrate, wherein the micro LED backlight array comprises a first sub-array of micro LEDs and a second sub-array of micro LEDs; and
forming a color conversion layer on the micro LED backlight array, wherein the color conversion layer comprises:
a first color conversion unit array comprising a plurality of first color conversion units, each of the plurality of first color conversion units comprising a first photoluminescence color conversion material that converts light emitted from the first sub-array of micro LEDs into light of a first color, wherein an orthogonal projection of the first color conversion unit array on the base substrate overlaps with an orthogonal projection of the first sub-array of micro-LEDs on the base substrate and does not overlap with an orthogonal projection of the second sub-array of micro LEDs on the base substrate; and
a second color conversion unit array comprising a plurality of second color conversion units, each of the plurality of first color conversion units comprising a second photoluminescence color conversion material that converts light emitted from the second sub-array of micro LEDs into light of a second color, wherein the light of the second color is different from the light of the first color, and an orthogonal projection of the second color conversion unit array on the base substrate overlaps with the orthogonal projection of the second sub-array of micro LEDs on the base substrate and does not overlap with the orthogonal projection of the first sub-array of micro LEDs on the base substrate.

11. The method of claim 10, wherein the micro LED backlight array further comprises a third sub-array of micro LEDs and the color conversion layer further comprises:
a third color conversion unit array comprising a plurality of third color conversion units, each of the plurality of third color conversion units comprising a third color light material that converts light emitted from the third sub-array of micro-LEDs into light of a third color, wherein the light of the third color is different from the light of the first color and the light of the second color, an orthogonal projection of the third color conversion unit array on the base substrate overlaps with an orthogonal projection of the third sub-array of micro LEDs on the base substrate and does not overlap with the orthogonal projections of the first sub-array of micro LEDs and the second sub-array of micro LEDs on the base substrate,
wherein forming the color conversion layer comprises:
providing an imprinting master, wherein the imprinting master comprises a protrusion array;
providing a soluble plate;
forming, by adopting a nano-imprinting process, a groove array of multiple rows and multiple columns on the soluble plate by using the protrusion array on the imprinting master, wherein the groove array comprises a first sub-array of grooves, a second sub-array of grooves and a third sub-array of grooves, and the first sub-array of grooves, the second sub-array of grooves and the third sub-array of grooves are sequentially arranged along row and column directions of the groove array;
filling a first photoluminescence color conversion material into the first sub-array of grooves, filling a second photoluminescence color conversion material into the second sub-array of grooves, and filling a third color light material into the third sub-array of grooves;
turning over the soluble plate filled with the first photoluminescence color conversion material, the second photoluminescence color conversion material and the third photoluminescence color conversion material and then placing the soluble plate on the micro-LED backlight array, wherein an orthographic projection of the first sub-array of grooves on the base substrate overlaps with the orthographic projection of the first sub-array of micro-LEDs on the base substrate and does not overlap with the orthographic projection of the second sub-array of micro LEDs and the orthographic projection of the third sub-array of micro LEDs on the base substrate; an orthographic projection of the second sub-array of grooves on the base substrate overlaps with the orthographic projection of the second sub-array of micro LEDs on the base substrate and does not overlap with the orthographic projection of the first sub-array of micro LEDs and the orthographic projection of the third sub-array of micro LEDs on the base substrate; and an orthographic projection of the third sub-array of grooves on the base substrate overlaps with the orthographic projection of the third sub-array of micro-LEDs on the base substrate and does not overlap with the orthographic projection of the first sub-array of micro LEDs on the base substrate and the orthographic projection of the second sub-array of micro LEDs on the base substrate; and
dissolving the soluble plate, leaving, on the micro LED backlight array, the first photoluminescence color conversion material on the micro LED backlight array to form the first color conversion unit array, leaving, on the micro LED backlight array, the second photoluminescence color conversion material to form the second color conversion unit array, and leaving, on the micro LED backlight array, the third color light material to form the third color conversion unit array.

12. The manufacturing method of claim 11, wherein the soluble plate is a polyvinyl alcohol plate.

13. The manufacturing method of claim 11, wherein the imprint master is one selected from hard glass, nickel, and PMMA.

14. The manufacturing method of claim 11, wherein the third color light material comprises a third photoluminescence color conversion material or a transparent material, and the third photoluminescence color conversion material converts light emitted from the third sub-array of micro-LEDs into the light of the third color.

15. The manufacturing method of claim 11, wherein the photoluminescence color conversion material comprises a quantum dot material or a fluorescent photoluminescence color conversion material, and the transparent material comprises scattering particles.

16. The manufacturing method of claim 11, wherein dissolving the soluble plate comprises dissolving the soluble plate with an aqueous solvent.

17. The manufacturing method of claim 11, wherein providing the micro LED backlight array comprises:
growing a micro LED array on a single wafer; and
transferring the micro LED array from the single wafer to the base substrate to form the micro LED backlight array.
